(19) United States
(12) Patent Application Publication
(10) Pub. No.: US 2008/0274579 A1
(43) Pub. Date: Nov. 6, 2008

(54) Wafer level image sensor package with die receiving cavity and method of making the same

(75) Inventors: Wen-Kun Yang, Hsin-Chu City (TW); Jui-Hsien Chang, Jhudong Township (TW); Tung-Chuan Wang, Yangmei Town (TW)

Correspondence Address: BACON & THOMAS, PLLC, 625 SLATERS LANE, FOURTH FLOOR, ALEXANDRIA, VA, 22314-1176, US

(73) Assignee: Advanced Chip Engineering Technology Inc., Hukou Township (TW)

(21) Appl. No.: 12/216,641

(22) Filed: Jul. 9, 2008

Related U.S. Application Data
(62) Division of application No. 11/708,476, filed on Feb. 21, 2007.

(51) Int. Cl. H01L 21/00

(52) U.S. Cl. 438/64; 257/E21.001

(57) ABSTRACT

The present invention provides a structure of package comprising a substrate with a die receiving cavity formed within an upper layer of the substrate, wherein terminal pads are formed on the upper surface of the substrate, the same plain as the micro lens. A die is disposed within the die receiving cavity by adhesion and a dielectric layer formed on the die and the substrate. A re-distribution metal layer (RDL) is formed on the dielectric layer and coupled to the die. An opening is formed within the dielectric layer and a top protection layer to expose the micro lens area of the die for Image Sensor chip. A protection layer (film) be coated on the micro lens area with water repellent and oil repellent to away the particle contamination. A transparent cover with coated IR filter is optionally formed over the micron lens area for protection.

### CROSS REFERENCES TO THE RELATED APPLICATIONS

This application is a divisional application of pending U.S. patent application Ser. No. 11/708,476, filed Feb. 21, 2007 (of which the entire disclosure of the pending, prior application is hereby incorporated by reference).

### FIELD OF THE INVENTION

This invention relates to a structure of wafer level package (WLP), and more particularly to a carrier (substrate) with die receiving cavity to receive an Image Sensor die for WLP.

### DESCRIPTION OF THE PRIOR ART

In the field of semiconductor devices, the device density is increased and the device dimension is reduced continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As semiconductor becomes more complicated, the traditional package technique, for example lead frame package, flex package, rigid package technique, can not meet the demand of producing smaller chip with high density elements on the chip.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For example, although utilizing WLP technique can reduce the CTE mismatch between IC and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer (RDL) into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Regarding the conventional method of packaging image sensor device either using the Chip On Board (COB) or using the Leadless Carrier Cavity (LCC) with wire bonding structure are suffered the yield problem during process, it was due to the particle contamination on the micro lens area and can not be removed after process.

Therefore, the present invention provides a FO-WLP structure without stacked built-up layer and RDL in order to reduce the package thickness by overcoming the aforementioned problem and also provide better board level reliability test of temperature cycling.

### SUMMARY OF THE INVENTION

The present invention provides a structure of package comprising a substrate with a die receiving cavity formed within an upper layer of the substrate wherein terminal pads are formed on the upper surface and exterior of the work piece. A die is disposed within the die receiving cavity by adhesion and a dielectric layer formed between the die and the substrate. A re-distribution metal layer (RDL) is formed on the dielectric layer and coupled to the die.

It should be noted that an opening is formed within the dielectric layer and a top protection layer to expose the micro lens area of the die for CMOS Image Sensor (CIS). Finally, a transparent cover with coating IR filter is optionally formed over the micron lens area for protection.

The image sensor chips has been coated with the protection layer (film) on the micro lens area; the protection layer (film) with the properties of water repellent and oil repellent that can away the particle contamination on the micro lens area; the thickness of protection layer (film) preferably around 0.1 um to 0.3 um and the reflection index close to air reflection index 1. The process can be executed by SOG (spin on glass) skill and it can be processed either in silicon wafer form or panel wafer form (preferably in silicon wafer form to avoid the particle contamination during further process). The materials of protection layer can be SiO₂, Al₂O₃ or Fluoro-polymer etc.

The dielectric layer includes an elastic dielectric layer, silicone dielectric based material, BCB or PI. The silicone dielectric based material comprises siloxane polymers (SINR), Dow Corning WL5000 series, or composites thereof. Alternatively, the dielectric layer comprises a photosensitive layer.

The material of the substrate includes organic epoxy type FR5, BT, PCB (print circuit board), alloy or metal. The alloy includes Alloy42 (42% Ni-58% Fe) or Kovar (29% Ni-17% Co-54% Fe). Alternatively, the substrate could be glass, ceramic or silicon.

### BRIEF DESCRIPTION OF THE DRAWINGS

FIG. 1 illustrates a cross-sectional view of a structure of fan-out WLP according to the present invention.

FIG. 1A illustrates a diagram of a protection layer of fan-out WLP according to the present invention.

FIG. 2 illustrates a cross-sectional view of a structure of fan-out WLP according to the present invention.

FIG. 3 illustrates a cross-sectional view of a structure of panel form fan-out WLP according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

The present invention discloses a structure of WLP utilizing a cavity formed into the substrate. A photosensitive material is coated over the die and the pre-formed substrate. Preferably, the material of the photosensitive material is formed of the elastic material.

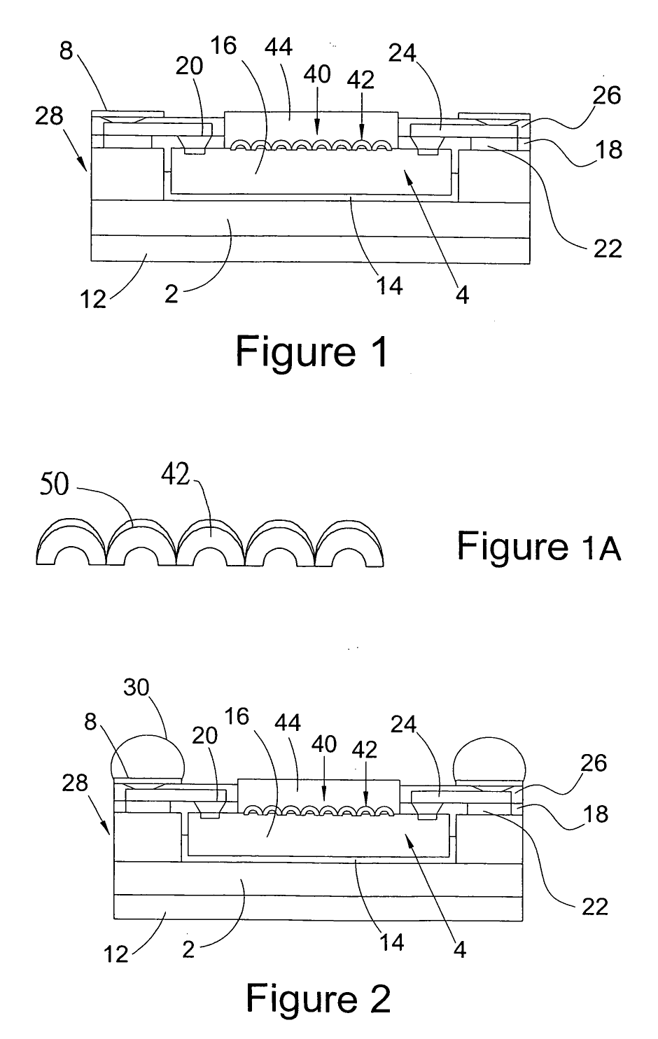

FIG. 1 illustrates a cross-sectional view of Fan-Out Wafer Level Package (FO-WLP) in accordance with one embodiment of the present invention. As shown in the FIG. 1, the structure of FO-WLP includes a substrate 2 having a die receiving cavity 4 formed therein to receive a die 16. Terminal Pads 8 are located on the upper surface of the substrate and situated substantially on the same plain level as the micro lens.

The die 16 is disposed within the die receiving cavity 4 on the substrate 2 and fixed by an adhesion (die attached) material 14. As known, contact pads (Bonding pads) 20 are formed on the die 16. A photosensitive layer or dielectric layer 18 is formed over the die and filling into the space between the die 16 and the side walls of the cavity 4. Pluralities of openings are formed within the dielectric layer 18 through the lithography process or exposure and development procedure. The RDL (re-distribution layer) 24, also referred to as metal trace 24, is formed on the dielectric layer 18 by removing selected portions of metal layer formed over the layer 18, wherein the RDL 24 keeps electrically connected with the die 16 through the I/O pads 20. A part of the material of the RDL will re-fills into the openings in the dielectric layer 18, thereby forming contact via metal 22 and bonding pad 20. A top protection layer 26 is formed to cover RDL 24. Another protective layer 12, solder mask epoxy, is formed beneath the bottom surface of the work piece.

The dielectric layer 18 is formed atop of the die 16 and substrate and fills the space surrounding the die 2. The aforementioned structure constructs LGA type package (peripheral type).

It should be noted that an opening 40 is formed within the dielectric layer 18 and the top protection layer 26 to expose the micro lens area 42 of the die 16 for CMOS Image Sensor (CIS). A protection layer (film) coating 50 (FIG. 1A) can be formed over the micro lens on the micro lens area 42. The opening 40 is typically formed by photolithography process, is well known to the skilled person in the art. In one case, the lower portion of the opening 40 can be opened during the formation of via opening. The upper portion of the opening 40 is formed after the deposition of the top protection layer 26. Alternatively, the whole opening 40 is formed after the formation of the top protection layer 26 by lithography. The image sensor chip is coated with the protection layer (film) on the micro lens area; the protection layer (film) with the properties of water repellent and oil repellent that can away the particle contamination on the micro lens area. The thickness of protection layer (film) is preferably around 0.1 um to 0.3 um and the reflection index is approximate to the air reflection index 1. The process can be executed by SOG (spin on glass) skill and it can be processed either on silicon wafer form or panel wafer form (preferably in silicon wafer form to avoid the particle contamination during further process). The materials of protection layer can be SiO₂, Al₂O₃ or Fluoro-polymer etc.

Finally, a transparent cover 44 with coating IR filter is optionally formed over the micron lens area 42 for protection. The transparent cover 44 is composed of glass, quartz, etc.

An alternative embodiment can be seen in FIG. 2, conductive balls 30 are formed atop the terminal pads 8. This type is called BGA (Ball Grid Array). Preferably, the material of the substrate 2 is organic substrate likes FR5, FR4, BT (Bismaleimide triazine), PCB with defined cavity or Alloy42 with pre etching circuit. The organic substrate with high Glass transition temperature (Tg) are epoxy type FR5 or BT (Bismaleimide triazine) type substrate. The Alloy42 is composed of 42% Ni and 58% Fe. Kovar can also be used, which composed of 29% Ni, 17% Co, 54% Fe. The glass, ceramic, silicon can be used as the substrate due to lower CTE.

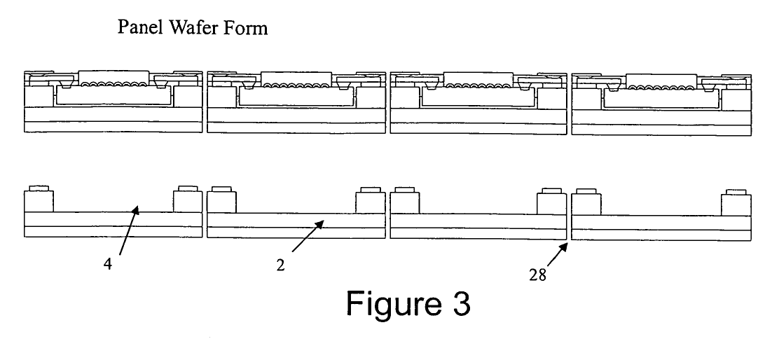

The substrate could be round type such as wafer type, the diameter could be 200, 300 mm or higher. It could be employed for rectangular type such as panel form. FIG. 3 illustrates the substrate 2 for the panel wafer form (cross section). In the upper portion of FIG. 3, the units 2 of FIG. 1 are arranged in a matrix form. A scribe line 28 is defined between the units 2 for separating each unit 2.

In one embodiment of the present invention, the dielectric layer 18 is preferably an elastic dielectric material which is made by silicone dielectric based materials comprising siloxane polymers (SINR), Dow Corning WL5000 series, and composites thereof. In another embodiment, the dielectric layer is made by a material comprising benzocyclobutene (BCB), epoxy, polyimides (PI) or resin. Preferably, it is a photosensitive layer for simple process.

In one embodiment of the present invention, the elastic dielectric layer is a kind of material with CTE larger than 100 (ppm/° C.), elongation rate about 40 percent (preferably 30 percent-50 percent), and the hardness of the material is between plastic and rubber. The thickness of the elastic dielectric layer 18 depends on the stress accumulated in the RDL/dielectric layer interface during temperature cycling test.

In one embodiment of the invention, the material of the RDL 24 comprises Ti/Cu/Au alloy or Ti/Cu/Ni/Au alloy; the thickness of the RDL 24 is between 2 um_and_{—}5 um. The Ti/Cu alloy is formed by sputtering technique also as seed metal layers, and the Cu/Au or Cu/Ni/Au alloy is formed by electro-plating; exploiting the electro-plating process to form the RDL can make the RDL thick enough to withstand CTE mismatching during temperature cycling. The metal pads 20 can be Al or Cu or combination thereof. If the structure of FO-WLP utilizes SINR as the elastic dielectric layer and Cu as the RDL metal, according to the stress analysis not shown here, the stress accumulated in the RDL/dielectric layer interface is reduced.

As shown in FIG. 1-2, the RDL metal 24 fans out of the die and communicates upwardly toward terminal pads 8 located on the upper section of the work piece (carrier or substrate). It is different from the prior art technology which stacks layers over the die, thereby increasing the thickness of the package. However, it violates the rule to reduce the die package thickness. On the contrary, the terminal pads are located on the exterior surface of the work piece. Therefore, the thickness shrinkage of the die package is apparently evident. The package of the present invention will be thinner than the prior art. Further, the substrate is pre-prepared and the cavity 4 is pre-determined prior to package. Hence, the throughput will be improved than ever. The present invention discloses a fan-out WLP without stacked built-up layers over the RDL.

The process for the present invention includes providing an alignment tool with alignment pattern formed thereon. Then, the pattern glues is printed on the tool (be used for sticking the surface of dice), followed by using pick and place fine alignment system with flip chip function to re-distribute the known good dies on the tool with desired pitch. The pattern glues will stick the chips on the tool. Subsequently, the die attached materials is printed on the die back side. Then, the panel bonder is used to bond the substrate on to die back side; the upper surface of substrate except the cavities also be stuck on the pattern glues, then vacuum curing and separate the tool with panel wafer.

Alternatively, the die bonder machine with fine alignment is employed, and the die attached materials is dispensed on the cavity of substrate. The die attached materials is thermally cured to ensure the die is attached on the substrate.

Once the die is re-distributed on the substrate, then, a clean up procedure is performed to clean the dice surface by wet and/or dry clean. Next step is to coat the dielectric materials on the panel, followed by performing vacuum procedure to ensure there is no bubble within the panel. Subsequently, lithography process is performed to open via and Al bonding pads, the micron lens area and/or the scribe line (optional). Plasma clean step is then executed to clean the surface of via holes and Al bonding pads. Next step is to sputter Ti/Cu as seed metal layers, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and metal wet etching metal to form the RDL metal trace. Subsequently, the next step is to coat or print the top dielectric layer and to open the micron lens area and the scribe line (optional).

After the ball placement or solder paste printing, the heat re-flow procedure is performed to re-flow on the substrate side (for BGA type). The testing is executed. Panel wafer level final testing is performed by using vertical probe card. After the testing, the substrate is sawed to singular the package into individual units. Then, the packages are respectively picked and placed the package (device) on the tray or tape and reel.

The advantages of the present invention are:

The substrate is pre-prepared with pre-form cavity; the size of cavity equal to die size plus around 100 um per/side; it can be used as stress buffer releasing area by filling the elastic dielectric materials to absorb the thermal stress due to the CTE difference between silicon die and substrate (FR5/BT). The packaging throughput will be increased (manufacturing cycle time was reduced) due to apply the simple build up layers on top the surface of die. The terminal pads are formed on the same plain level as the dice active surface (pre-formed). The dice placement process is the same as the current process. No core paste (resin, epoxy compound, silicone rubber, etc.) filling is necessary for the present invention. There is no CTE mismatching issue during panel form process and the deepness between die and substrate FR5 is only around ˜25 um-30 um (be used for thickness of die attached materials), the surface level of die and substrate can be the same after die is attached on the cavities of substrate. Only silicone dielectric material (preferably SINR) is coated on the active surface and the substrate (preferably FR5 or BT) surface. The contacting via structure is opened by using photo mask process only due to the dielectric layer (SINR) is photosensitive layer for opening the contacting Via. Vacuum process during SINR coating is used to eliminate the bubble issue. The die attached material is printed on the back-side of dice before substrate be bonded together with dice (chips). The reliability for both package and board level is better than ever, especially, for the board level temperature cycling test, it was due to the CTE of substrate and PCB mother board are identical, so, no thermal mechanical stress be applied on the solder bumps/balls. The cost is low and the process is simple. It is easy to form the combo package (dual dice package).

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A method for forming semiconductor device package comprising:
providing a substrate with a die receiving cavity formed within an upper layer of said substrate, wherein terminal pads are formed on said upper surface of said substrate;
using a pick and place fine alignment system to re-distribute known good dice image sensor chips on a tool with desired pitch;
attaching adhesive material on die back side;
bonding said substrate on to said die back side, and curing then separating said tool; coating a dielectric material on said substrate, followed by performing vacuum procedure;
opening via structure, a micro lens area and I/O pads;
sputtering seed metal layer over said dielectric layer and said via structure and said I/O pads;
forming RDL metal on said dielectric layer;
forming a top dielectric layer over said RDL; and
opening said top dielectric layer to open said micro lens area.

2. The method of claim 1, the image sensor chip with a protection layer formed on said the micro lens area to protect the micro lens away the particle contamination.

3. The method of claim 1, further comprising a step of forming a transparent cover with coating IR filter over said micro lens area.
